(19) United States
(12) Patent Application Publication
(10) Pub. No.: US 2007/0155141 A1
(43) Pub. Date: Jul. 5, 2007

(54) Semiconductor device and method for fabricating the same

(75) Inventor: Sang Hyun Ban, Seongnam-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/644,178

(22) Filed: Dec. 22, 2006

(30) Foreign Application Priority Data
Dec. 29, 2005 (KR) 10-2005-0133964

(51) Int. Cl. H01L 33/00

(52) U.S. Cl. 438/508

(57) ABSTRACT

A semiconductor device and method for manufacturing the same. A cobalt silicide layer is placed on a silicon germanium layer through an MOCVD process, by forming a silicon germanium thin film on a first conductive type silicon substrate, implanting second conductive type impurities onto the silicon germanium thin film, and depositing a cobalt silicide (CoSi₂) layer on the silicon germanium thin film, into which the second conductive type impurities are implanted, through a chemical vapor deposition (CVD) scheme.

### BACKGROUND OF THE INVENTION

1. Field of the Invention

The present invention relates to a semiconductor device and a method for manufacturing the same. More specifically, the present invention relates to a semiconductor device and a method for manufacturing the same, capable of forming a cobalt silicide layer (CoSi₂) on a silicon (Si) substrate, for instance including a silicon germanium (SiGe) layer.

2. Description of the Related Art

If cobalt silicide (CoSi₂) is formed on a silicon germanium alloy, the junction between the silicon germanium alloy and the cobalt silicide may form a Schottky contact or an ohmic contact. Accordingly, cobalt silicide (CoSi₂) is widely used for manufacturing semiconductor devices.

Since cobalt silicide has low specific resistance and easily forms an epitaxial layer on silicon, cobalt silicide has been used extensively for highly integrated circuits. Accordingly, the interfacial surface reactions and electrical characteristics of the epitaxial cobalt silicide layer formed on a silicon germanium layer, in multi-crystalline cobalt silicide/silicon germanium systems, have been researched and developed. Such studies are mainly focused on mutual reactions between the cobalt metal layer and the silicon germanium layer during the annealing process performed after forming the cobalt metal layer on the silicon germanium layer. This is because it is desirable to prevent the interfacial surface between the cobalt silicide layer and the silicon germanium layer from being rough and the cobalt silicide layer from being mixed with the silicon germanium layer.

As a scheme for directly growing an epitaxial cobalt silicide layer on a silicon germanium layer, only a molecular beam epitaxy (MBE) method is known. It is also known to form the epitaxial cobalt silicide layer on the silicon layer by performing an annealing process after depositing a cobalt-carbon alloy layer on the silicon layer, through a metal organic chemical vapor deposition (MOCVD) process.

However, there has been no attempt to directly form an epitaxial cobalt silicide on a silicon germanium layer through the MOCVD method. Since the MOCVD method has superior efficiency and can be widely used, compared with MBE, the MOCVD method is more suitable for manufacturing semiconductor devices.

### SUMMARY OF THE INVENTION

Accordingly, the present invention has been made to solve the above-mentioned problems, and an object of the present invention is to provide a semiconductor device and method for manufacturing the same, in which a cobalt silicide layer can be formed on a silicon germanium layer through a CVD process (such as an MOCVD process) to manufacture a semiconductor device continently and simply.

Another object of the invention is to provide a semiconductor device and a method for manufacturing the same, in which an epitaxial cobalt silicide layer has a low sheet resistance. Another object is to provide a method for manufacturing a semiconductor device, comprising: forming a silicon germanium thin film on a silicon substrate; implanting impurities into the silicon germanium thin film; and depositing a cobalt silicide (CoSi₂) layer on the silicon germanium thin film through an metal-organic chemical vapor deposition (MOCVD) scheme using cyclopentadienyl dicarbonyl cobalt.

In order to accomplish the objects, there is provided a semiconductor device including a silicon layer, a silicon germanium layer on an upper side of the silicon layer, and a cobalt silicide layer on the upper side of the silicon germanium layer. The cobalt silicide layer may contain carbon-based impurities, which may result from its formation using a metal-organic chemical vapor deposition (MOCVD) scheme.

According to another aspect of the present invention, there is provided a method for manufacturing a semiconductor device, the method including the steps of forming a silicon germanium thin film on a silicon substrate having a first conductivity type, implanting second conductive type impurities in the silicon germanium thin film, and depositing a cobalt silicide (e.g., CoSi₂) layer on the silicon germanium thin film through a chemical vapor deposition (CVD) process.

Another aspect of the invention concerns a method for manufacturing a semiconductor device, including forming a silicon germanium thin film on a silicon substrate, implanting impurities into the silicon germanium thin film, and depositing a cobalt silicide (e.g., CoSi₂) layer on the silicon germanium thin film through metal-organic chemical vapor deposition (MOCVD) using cyclopentadienyl dicarbonyl cobalt.

According to the present invention, a cobalt silicide layer can be formed on a silicon germanium layer through an MOCVD scheme, so it is possible to more conveniently and simply manufacture a semiconductor device including such materials.

### BRIEF DESCRIPTION OF THE DRAWINGS

FIGS. 1A and 1B are graphs showing an XRD pattern for CoSi₂/p-SiGe/n-Si samples fabricated according to the present invention.

FIG. 2 is a graph showing the sheet resistance of a cobalt silicide layer in CoSi₂/p-SiGe/n-Si samples fabricated according to the present invention.

### DETAILED DESCRIPTION OF THE INVENTION

Hereinafter, a method for fabricating a semiconductor device according to the present invention will be described in detail with reference to accompanying drawings.

According to the present invention, cobalt silicide is deposited through an MOCVD process by using cyclopentadienyl dicarbonyl cobalt (Co(η⁵-C₅H₅)(CO)₂) as a precursor, thereby forming a cobalt silicide layer on a silicon germanium layer.

Hereinafter, a method for fabricating a semiconductor device according to an embodiment of the present invention will be described in detail.

A p-type silicon germanium epitaxial thin film is deposited on an n-type silicon substrate through a CVD scheme such that the p-type silicon germanium epitaxial thin film has a thickness of 20-100 nm, preferably about 50 nm.

In more detail, the CVD scheme is performed by introducing a silane gas (e.g., SiH₄) at about 20 sccm (standard cubic centimeters per minute), a germanium hydride gas (e.g., GeH₄) at about 100 sccm, a hydrogen gas at about 20,000 sccm under a chamber pressure of about 3,990 Pa and a temperature of about 650° C.

A source gas of boron hydride (e.g., B₂H₆) diluted with hydrogen (H₂) is introduced in order to inject boron into the silicon germanium epitaxial thin film. The use of boron is only an example for illustrative purposes. Any materials that can be used as p-type dopants, may be used.

As a result, a p-type silicon germanium layer is formed on the silicon substrate, thereby forming a p-SiGe/n-Si substrate. The p-SiGe/n-Si substrate is cleaned by using a solution of sulfuric acid (H₂SO₄) and hydrogen peroxide (H₂O₂), and then is rinsed using deionized water. Thereafter, the p-SiGe/n-Si substrate is put into a HF solution of 1%, and then rinsed by using deionized water. The cleaned p-SiGe/n-Si substrate is put into an MOCVD reactor. Thereafter, cyclopentadienyl dicarbonyl cobalt is put into the MOCVD reactor as a precursor under a pressure of from 50 to 200 mT (e.g., about 110 mT) and a reaction temperature of from 500 to 800° C. (e.g., about 650° C.), thereby depositing a cobalt silicide layer on the p-SiGe/n-Si substrate. At this time, hydrogen gas at a flow rate of from 1 to 100 sccm (e.g., about 10 sccm) may be used as a carrier gas. Alternatively or additionally, the carrier gas may comprise a noble gas (e.g., He, Ne, Ar, etc.). Through this scheme, a CoSi₂/p-SiGe/n-Si sample is completely manufactured.

In order to determine the influence exerted on the CoSi₂/p-SiGe/n-Si sample when an annealing process is performed with respect to the CoSi₂/p-SiGe/n-Si sample, a rapid thermal annealing (RTA) process is performed with respect to the CoSi₂/p-SiGe/n-Si sample under a temperature of 600, 700, or 800° C. for 30-300 sec (e.g., 180 sec). In order to determine the state of the cobalt silicide layer, X-ray diffusion patterns for a CoSi₂/p-SiGe/n-Si sample that was not subjected to the RTA process, and COSi₂/p-SiGe/n-Si samples that were subjected to the RTA process, are obtained by using an automatic diffractometer. In this case, CuK radiation is used as the light source.

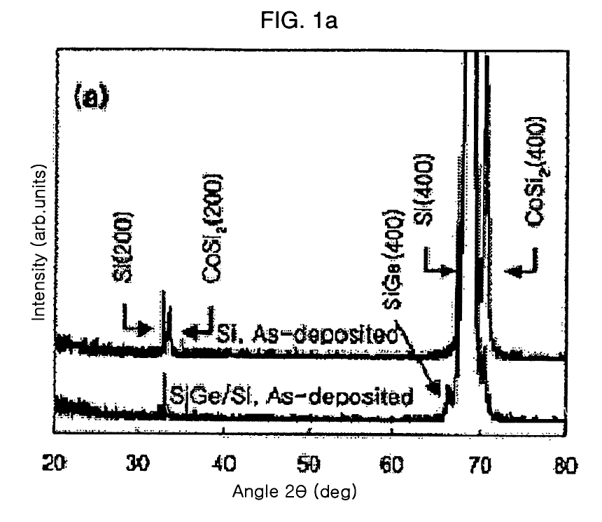

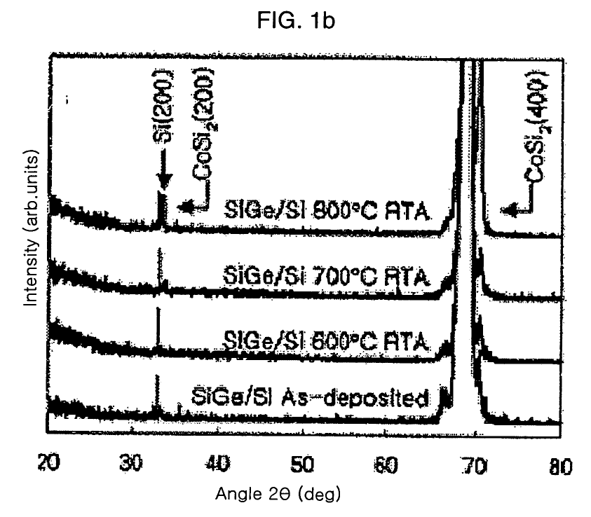

FIGS. 1A and 1B are graphs showing the XRD patterns for the samples. In particular, FIG. 1A is a graph showing a sample manufactured by directly depositing the cobalt-carbon alloy layer on the silicon substrate through an MOCVD process and a sample manufactured according to the present invention. FIG. 1B is a graph showing samples manufactured through an annealing process under various temperatures according to the present invention.

Referring to FIGS. 1A and 1B, a peak corresponding to cobalt silicide (CoSi₂) is shown in the CoSi₂/p-SiGe/n-Si sample which was not subjected to the RTA annealing process after depositing the cobalt silicide layer (“As-deposited”). Accordingly, it is possible to determine that the cobalt silicide layer has formed on the silicon germanium layer only by deposition according to the present invention.

Meanwhile, as shown in FIG. 1B in more detail, in the CoSi₂/p-SiGe/n-Si samples which were subjected to the RTA annealing process under various temperatures, such as 600° C. RTA, 700° C. RTA, or 800° C. RTA process, the peak intensity corresponding to cobalt silicide (CoSi₂) rapidly increases as the annealing temperature increases. In contrast, the peak intensity corresponding to a p-type silicon germanium layer (p-SiGe) decreases. This implies that silicon of the p-type silicon germanium layer is consumed in order to form the cobalt silicon layer during the RTA annealing process.

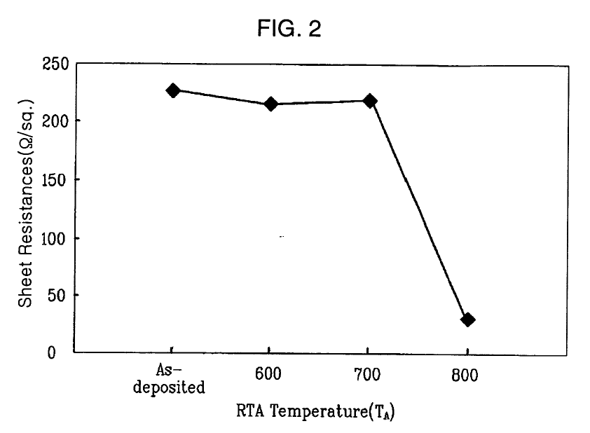

The graph of FIG. 2 shows sheet resistance of the CoSi₂/p-SiGe/n-Si sample, which is not subject to the RTA annealing process (As-deposited), and the CoSi₂/p-SiGe/n-Si samples which are subject to the RTA annealing process under various temperatures such as 600° C., 700° C. and 800° C. after depositing the cobalt silicide layer.

As can be recognized from FIG. 2, in the CoSi₂/p-SiGe/n-Si samples that are not subjected to the RTA annealing process after depositing the cobalt silicide layer, the cobalt silicide layer shows sheet resistance of about 230 Ω/sq. In contrast, sheet resistance of the grown cobalt silicide layer in the CoSi₂/p-SiGe/n-Si samples that are subjected to the RTA annealing process rapidly decreases. In other words, as the annealing temperature increases, the sheet resistance decreases. In detail, when the annealing temperature is 800° C., the sheet resistance of the cobalt silicide layer decreases to 30 Ω/sq. Thus, the cobalt silicide formed using the present invention may have a sheet resistance of from 20 Ω/sq to 50 Ω/sq.

Accordingly, it can be recognized from the figures that the cobalt silicide layer is formed on the silicon germanium layer through the MOCVD process, and then an RTA annealing process is performed under a high temperature of 800° C., thereby growing a cobalt silicide layer having low sheet resistance.

According to the present invention, the cobalt silicide layer can be formed on the silicon germanium layer through the MOCVD scheme, and the sheet resistance of the cobalt silicide layer can be decreased through the following RTA annealing process. In addition, it is possible to conveniently simplify the manufacturing process through the MOCVD process.

As described above, the scheme of forming a cobalt silicide layer on a silicon germanium layer is employed for a process of forming a conductive layer in addition to a process of filling metal in a contact hole of a semiconductor device, so that it is possible to reduce the size of the semiconductor device and improve the yield rate of the semiconductor device.

Although the invention has been described in terms of a cobalt silicide layer being formed on a p-type silicon germanium layer, the present invention is not limited thereto. According to another embodiment, the conductive type impurity can be easily changed according to the known uses of the silicon germanium layer.

While the invention has been shown and described with reference to certain preferred embodiments it will be understood by those skilled in the art that various changes in form and detail may be made without departing from the spirit and scope of the invention as defined by the appended claims.

What is claimed is:

1. A method for manufacturing a semiconductor device, comprising:
forming a silicon germanium thin film on a silicon substrate having a first conductive type impurity;
implanting a second conductive type impurity in the silicon germanium thin film; and
depositing a cobalt silicide (CoSi₂) layer on the silicon germanium thin film through a chemical vapor deposition (CVD) process.

2. The method of claim 1, wherein forming the silicon germanium thin film comprises a chemical vapor deposition (CVD) process.

3. The method of claim 1, wherein the silicon germanium thin film has a thickness of about 50 nm.

4. The method of claim 1, wherein the second conductive type impurity includes a p-type impurity.

5. The method of claim 1, wherein the second conductive type impurity includes boron (B).

6. The method of claim 1, further comprising cleaning the deposited cobalt silicide layer using a solution of sulfuric acid (H₂SO₄) and hydrogen peroxide (H₂O₂).

7. The method of claim 6, further comprising a step of rinsing the cobalt silicide layer using deionized water after cleaning the cobalt silicide layer.

8. The method of claim 1, wherein depositing the cobalt silicide layer comprises using cyclopentadienyl dicarbonyl cobalt as a precursor.

9. The method of claim 8, wherein depositing the cobalt silicide layer comprises a metal-organic chemical vapor deposition (MOCVD) process under pressure of about 110 mT and a temperature of about 650° C.

10. The method of claim 1, further comprising an annealing process after depositing the cobalt silicide layer.

11. The method of claim 10, wherein the annealing process is includes rapid thermal annealing (RTA) process.

12. The method of claim 10, wherein the rapid thermal annealing (RTA) process is performed at a temperature of about 800° C. or less.

13. The method of claim 1, wherein the chemical vapor deposition (CVD) process for forming the silicon germanium thin film comprises using a silane gas, a germanium hydride gas, and hydrogen (H₂) gas as source gases.

14. The method of claim 13, wherein the CVD process uses the silane gas at a flow rate of about 20 sccm, the germanium hydride gas at a flow rate of about 100 sccm, and hydrogen (H₂) gas at a flow rate of about 20,000 sccm.

15. A method for manufacturing a semiconductor device, comprising:
forming a silicon germanium thin film on a silicon substrate;
implanting impurities into the silicon germanium thin film; and
depositing a cobalt silicide (CoSi₂) layer on the silicon germanium thin film through an metal-organic chemical vapor deposition (MOCVD) scheme using cyclopentadienyl dicarbonyl cobalt.

16. The method of claim 15, wherein the cobalt silicide layer is deposited, and then is subject to an annealing process.

17. The method of claim 16, wherein, annealing the cobalt silicide layer reduces the silicon germanium thin film and expands the cobalt silicide layer.

18. A semiconductor device comprising:
a silicon layer;
a silicon germanium layer on the upper side of the silicon layer; and
a cobalt silicide layer on the upper side of the silicon germanium layer, formed by a metal-organic chemical vapor deposition (MOCVD) process.

19. The semiconductor device of claim 18, wherein the cobalt silicide layer uses cyclopentadienyl dicarbonyl cobalt as a precursor.

20. The semiconductor device of claim 18, wherein the silicon germanium thin film has a thickness of about 50 nm.
